(19) United States
(12) Patent Application Publication
(10) Pub. No.: US 2018/0026102 A1
(43) Pub. Date: Jan. 25, 2018

(54) Power semiconductor device

(71) Applicant: The University of Warwick, Coventry, Warwickshire (GB)

(72) Inventors: Peter Gammon, Coventry, Warwickshire (UK); Chun Wa Chan, Coventry, Warwickshire (UK)

(21) Appl. No.: 15/547,682

(22) PCT Filed: Feb. 18, 2015
(86) PCT No.: PCT/GB2015/050467

§ 371 Date: Jul. 31, 2017

(51) Int. Cl. H01L 29/16; H01L 29/739; H01L 29/78; H01L 29/06; H01L 29/165; H01L 29/66

(52) U.S. Cl. CPC H01L 29/1608; H01L 29/165; H01L 29/66681; H01L 29/7816; H01L 29/063; H01L 29/7393

(57) ABSTRACT

A power semiconductor device is described. The device comprises a silicon carbide substrate and a layer of monocrystalline silicon having a thickness t_{Si} no more than 5 μm disposed directly on the substrate or directly on an interfacial layer having a thickness no more than 100 nm which is disposed directly on the substrate. The device comprises a lateral transistor, such as a laterally-diffused metal oxide semiconductor transistor or lateral insulated gate bipolar transistor, comprising first and second contacts laterally-spaced contact regions disposed in the monocrystalline silicon layer.

### FIELD OF THE INVENTION

The present invention relates to a power semiconductor device, in particular a silicon-on-silicon carbide semiconductor device.

### BACKGROUND

Semiconductor devices capable of operating in hostile environments and/or at high temperatures (e.g. >300° C.) are of great interest in a wide range of fields, including (but not limited to) oil and gas exploration, aerospace, transport and renewable energy.

Elevated temperatures, however, tend to have a detrimental effect on existing silicon-based device. As ambient temperature increases up to 300° C. and beyond, p-n junction leakage current increases exponentially and the drift and channel resistances increase linearly, resulting in increased power loss and in a greater susceptibility to thermal runaway due to self-heating. Power semiconductor devices, such as insulated-gate bipolar transistors (IGBTs) and metal-oxide-semiconductor field-effect transistors (MOSFETs), are particularly vulnerable since self-heating effects due to conduction and switching losses can lead to high junction-to-case temperatures.

Silicon carbide (SiC) semiconductor devices are stable up to and beyond 300° C. and are less prone to self-heating on account of silicon carbide having a high thermal conductivity (three times that of silicon) and an exceptionally low intrinsic carrier concentration. However, the SiC/SiO₂ interface tends to suffer poor channel mobility which leads to very high channel resistances. Consequently, silicon-based devices tend to be used in low- to medium-voltage applications (i.e. below 600 V) at temperatures below 300° C. In fact, low- to medium-voltage applications are most commonly served by vertical, bulk silicon devices such as (in order of voltage rating), MOSFETs, superjunction MOSFETs and IGBTs.

Lateral, power MOSFETs, exhibiting blocking voltages up to 600 V and beyond, have been implemented in thick-film silicon-on-insulator (SOI) having a thick, buried oxide (i.e. silicon dioxide). This type of device has an advantage that it is possible to support power and logic circuits on the same substrate, but isolate different parts of the circuits using the buried oxide. This arrangement, however, has not been widely adopted due, in part, to higher processing costs, but mainly because of poor thermal performance: the buried oxide is not only electrically insulating, but also thermally insulating. Consequently, heat resulting from ohmic losses and device switching is not efficiently removed. Thus, the junction-to-case temperature (i.e. the difference in temperature between the active semiconductor area and the ambient surroundings) can exceed 100° C. even at low ambient temperatures. In the hostile environments, however, the ambient temperature can exceed 200° C.

Even though considerable effort has been directed at developing three-step cubic silicon carbide (3C-SiC) on silicon substrate devices, comparatively little work has gone into investigating device involving silicon on a silicon carbide substrate.

Structures have been fabricated in which silicon is bonded onto an oxidized silicon carbide substrate as described in, for example, F. Udrea et al.: “Silicon/Oxide/Silicon Carbide (SiOSiC)—A New Approach to High-Voltage, High-Frequency Integrated Circuits”, Materials Science Forum, volume 389-393, page 1255 (2002) and S. G. Whipple “Demonstration of Hybrid Silicon-on-Silicon Carbide Wafers and Electrical Test Structures with Improved Thermal Performance”, MRS Proceedings, volume 911 (2006). The introduction of an oxide layer can help to reduce leakage through the substrate when the devices are off, better isolate the power device and make the bonding process easier. This approach, however, re-introduces self-heating effects.

Heterostructures have been also investigated in which silicon is in direct contact with an underlying silicon carbide substrate.

M. R. Jennings et al.: “Si/SiC Heterojunctions Fabricated by Direct Wafer Bonding” Electrochemical and Solid State Letters, volume 11, pages H306-H308 (2008) and A. Pérez-Tomás et al.: “Si/SiC bonded wafer: A route to carbon free SiO₂ on SiC”, Applied Physic Letters, volume 94, page 103510 (2009) describe silicon-silicon carbide heterojunction structures produced using a layer-transfer process.

H. Shinohara et al.: “Si metal-oxide-semiconductor field-effect transistor on Si-on-SiC directly bonded wafers with high thermal conductance”, Applied Physics Letters, volume 93, page 122110 (2008) and Y. Sasada et al.: “Junction formation via direct bonding of Si and 6H-SiC”, Materials Science Forum, volume 778-780, page 714 (2014) describes bonding silicon wafers directly onto 6H-SiC wafers. Wafer thinning and polishing is used to reduce the wafer thickness to 1 μm. At 300° C., the channel mobility and, thus, on-state conductance of CMOS-like Si/SiC MOSFET is degraded by only 10% compared with 83% for a silicon bulk device.

S. Lotfi, et al.: “LDMOS-transistors on semi-insulating silicon-on-polycrystalline-silicon carbide substrates for improved RF and thermal properties”, Solid-State Electronics, volume 70, pages 14-19 (2012) and L. G. Li et al.: “Dynamics of SiO₂ Buried Layer Removal from Si-SiO₂-Si and Si-SiO₂-SiC Bonded Substrates by Annealing in Ar”, Journal of Electronic Materials, volume 43, pages 541-547 (2014) describe implementing lateral MOSFETs structures on silicon/polysilicon/polysilicon carbide substrates for room-temperature, low-voltage RF applications.

The silicon/silicon carbide devices showed that self-heating in the forward characteristics was avoided, unlike comparative SOI devices. In the silicon/silicon carbide devices, however, off-state leakage currents marginally increased, while breakdown voltage (even though not optimised) halved in the worst case. Furthermore, the SOI devices demonstrated better turn-on voltage, sub-threshold slope and maximum oscillation frequency.

### SUMMARY

According to a first aspect of the present invention there is provided a power semiconductor device. The device comprises a silicon carbide, diamond or aluminium nitride substrate and a layer of monocrystalline silicon having a thickness no more than 5 μm disposed directly on the substrate or directly on an interfacial layer having a thickness no more than 100 nm which is disposed directly on the substrate. The device comprises a lateral transistor comprising first and second contact laterally-spaced contact regions disposed in the monocrystalline silicon layer.

Thus, the substrate allows a thinner layer of silicon to be used, for example, as thin as 300 nm or even less to increase the breakdown voltage.

The substrate preferably comprises a 6H-SiC substrate. The substrate may be semi-insulating. The substrate may be doped n-type or p-type. The substrate may have a thickness no more than 300 μm or no more than 50 μm.

The silicon layer may have a thickness no more than 2 μm, no more than 1 μm or no more than 300 nm. The silicon layer may comprise an n-type region. The silicon layer may comprise a p-type region The interfacial layer may comprise a layer of dielectric material such as silicon dioxide (SiO₂), silicon nitride (SiₓN_{y}), silicon oxynitride (SiOₓN_{y}), aluminium oxide (Al₂O₃) or hafnium oxide (HfO₂). The interfacial layer may comprise a semiconductor material, such as a layer of polycrystalline silicon.

The interfacial layer may have a thickness no more than 50 nm. The interfacial layer may have a thickness of at least 5 nm.

The lateral transistor may be a metal oxide semiconductor field effect transistor (MOSFET) or an insulated gate bipolar transistor (IGBT).

According to a second aspect of the present invention there is provided a method of operating a power semiconductor device at a temperature of at least 200° C. The method comprises applying a drain-source voltage of at least 100 V. The method may comprise applying a drain-source voltage up to 600 V or even 1200 V. The temperature may be at least 250° C.

### BRIEF DESCRIPTION OF THE DRAWINGS

Certain embodiments of the present invention will now be described, by way of example, with reference to the accompanying drawings, in which:

FIG. 1 is a vertical section of a first semiconductor device;

FIG. 2 is a vertical section of a second semiconductor device;

FIG. 3 is a vertical section of a third semiconductor device;

FIG. 4 is a vertical section of a fourth semiconductor device;

FIG. 5 is a vertical section of a fifth semiconductor device;

FIG. 6 is a vertical section of a sixth semiconductor device;

FIG. 7 is a process flow diagram of a method of fabricating a semiconductor device;

FIGS. 8A to 8D are vertical sections through a semiconductor device at different stages during fabrication;

FIG. 9 illustrates plots of simulated current density against reverse drain-source bias;

FIG. 10 are greyscale plots of electric field distribution; and

FIG. 11 show simulated plots of current density and internal junction temperature.

### DETAILED DESCRIPTION OF CERTAIN EMBODIMENTS

In the following, like parts are denoted by like reference numerals.

### Device Structures

### First Power Semiconductor Device

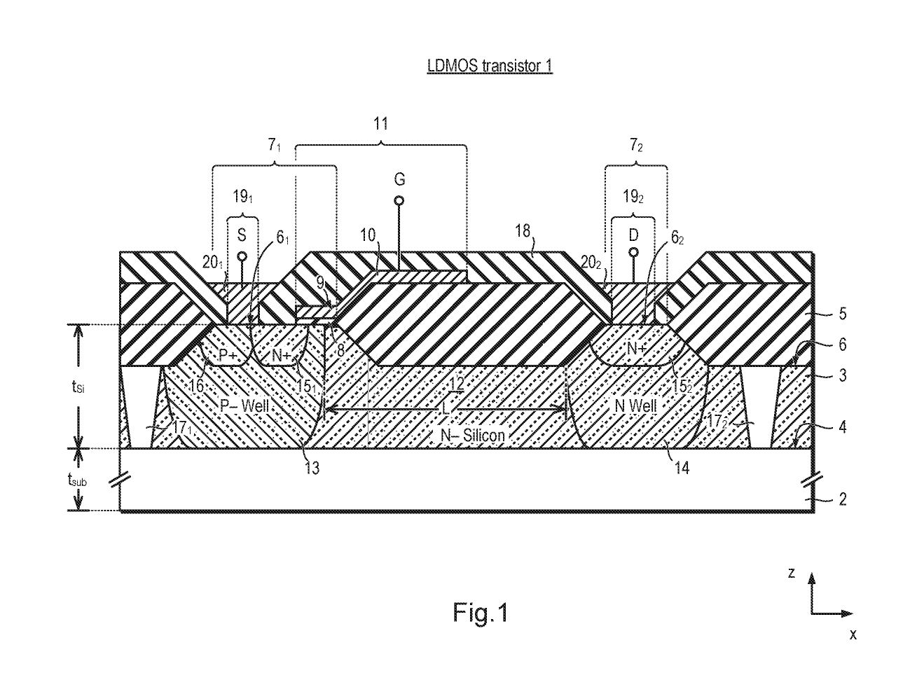

Referring to FIG. 1, a first power semiconductor device comprising a first laterally-diffused metal oxide semiconductor (LDMOS) transistor 1 is shown.

The device comprises a semi-insulating, six-step hexagonal silicon carbide (6H-SiC) substrate 2. The substrate 2 has a thickness, t_{sub}, of 300 μm. The substrate 2 can be thinner and the substrate thickness, t_{sub}, can be as small as 50 μm.

A layer 3 of lightly-doped n-type monocrystalline silicon is disposed on an upper surface 4 of the substrate 2. A field oxide 5 is located at an upper surface 6 of the silicon layer 3 and has first and second windows 7₁, 7₂ defining first and second laterally-separated upper surfaces 6₁, 6₂ of the silicon layer 3.

A gate oxide 8 is disposed within the first window 7₁ on the upper surface 6₁ of the silicon layer 3. The gate oxide 8 runs along the upper surface 6₁ of the silicon layer 3 and abuts the field oxide 5 thereby forming a step 9. A layer of heavily doped n-type polycrystalline silicon 10 (which may also be referred to as the “gate poly”) is disposed on the gate oxide 8 and runs over the step 9 onto the field oxide 5. Additionally or alternatively, a layer of metallization, such as aluminium (Al), can be used. The gate poly 10 includes an extension 11. Silicon dioxide spacers (not shown) may be formed on the sides of the gate poly 10. The silicon layer 3 provides a drift region 12.

A p-type body 13 in the form of a lightly-doped p-type diffusion well is disposed within the silicon layer 3 at the first upper surface 6₁. The p-type body 13 extends laterally under the gate oxide 8. An n-type buffer 14 in the form of a moderately-doped n-type well is disposed within the silicon layer 3 at the second upper surface 6₂. First and second contact regions 15₁, 15₂ (herein referred to as “source region” and “drain region” respectively) in the form of respective heavily-doped, shallow n-type diffusion wells are disposed in the p-type well 13 and n-type buffer 14 at the first and second upper surfaces 6₁, 6₂. A body contact region 16 in the form of a heavily-doped, shallow p-type diffusion well is disposed at the first upper surface 6₁ adjacent to the source contact 15₁.

Deep trench isolation in the form of oxide-lined, poly silicon-filled trenches 17₁, 17₂ extending downwardly from the field oxide 5 through the silicon layer 3 to the substrate 2 are used to electrically isolate the transistor 1 from neighbouring transistor (not shown).

A layer 18 of silicon dioxide runs over the gate poly 10 and the field oxide 5, and has windows 19₁, 19₂. Layers 20₁, 20₂ of metallization are disposed on the silicon dioxide layer 18 covering windows 19₁, 19₂. The first metallisation layer 20₁ provides a source terminal S and the second metallisation layer 20₂ provides a drain terminal D. The metallization layers 20₁, 20₂ each comprise a bi-layer comprising a high-barrier metal silicide base layer comprising, for example, platinum silicide (PtSi), and a high-conductivity overlayer comprising, for example, aluminium (Al).

The silicon layer 3 has a thickness, t_{Si}, of 1 μm. However, the silicon layer 3 can be thicker, for example, up to 2 μm or even 5 μm. Preferably, however, the silicon layer 3 is as thin as possible and can be as thin as 300 nm. The current rating of the device can be increased by making the gate width larger. The gate width may be at least 100 μm, at least 500 μm, at least 1 mm or at least 2 mm.

The contacts regions 15₁, 15₂, source S and drain D may have one or more different geometries or layouts.

For example, the contacts regions 15₁, 15₂, source S and drain D may extend along the y-axis so as to form generally parallel stripes. The contacts regions 15₁, 15₂ may have the same length along the y-axis. However, one contact region 15₁, 15₂ (and its corresponding metallization S, D) may be longer than the other contact region 15₁, 15₂ (and its corresponding metallization S, D), thereby giving the device 1 a wedge-like appearance in plan view.

Alternatively, the device 1 may be arranged such that one of the contact regions 15₁, 15₂ (and its corresponding metallization S, D) is disposed at the centre of the device 1 and the other contact region 15₁, 15₂ (and its corresponding metallization S, D) is arranged as a concentric ring, thereby giving the device a circular appearance in plan view.

The power semiconductor device can have one or more advantages.

Being silicon-based, the transistor 1 may not suffer high channel resistance problems typically exhibited by silicon carbide devices.

Furthermore, the 6H-SiC substrate 2 can be semi-insulating and can provide electrical isolation due to having a wide band gap which results in low conductivity: the resistivity of the substrate can exceed 10⁷ Ωcm. The 6H-SiC substrate 2 has a high breakdown electric field which can increase breakdown voltage by a factor of about two to three times, as the vertical electric field is allowed to spread through silicon carbide. Moreover, 6H-SiC has the highest thermal conductivity of all the common silicon carbide polytypes and so can efficiently conduct heat away from the active area of the device thereby reducing the effect of self-heating.

Thus, the power semiconductor device, in comparison to bulk silicon or silicon-on-insulator devices, can be used in environments at higher ambient temperatures, to operate more efficiently at a given temperature and/or to run at a higher power throughput.

### Second Power Semiconductor Device

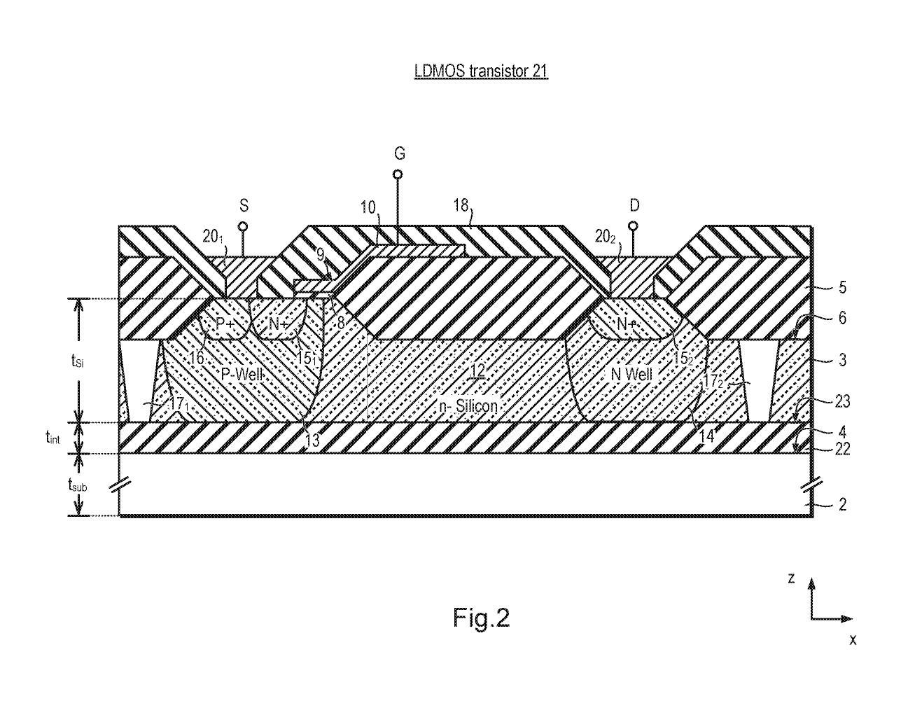

Referring to FIG. 2, a second power semiconductor device comprising a second LDMOS transistor 21 is shown.

The second power semiconductor device is substantially the same as the first power semiconductor device except that an interfacial layer 22 is interposed between the substrate 2 and the silicon layer 3. The interfacial layer 22 is in direct contact with the upper surface 4 of the substrate and the silicon layer 3 is in direct contact with an upper surface of the interfacial layer 22.

The interfacial layer 22 can aid bonding of the silicon layer 3 and the substrate 2.

The interfacial layer 22 may consist of a dielectric material, such as silicon dioxide, silicon nitride (SiₓN_{y}), aluminium oxide (Al₂O₃) or hafnium oxide (HfO₂). The interfacial layer 22 may consist of polycrystalline silicon.

The interfacial layer 22 (whether it is a dielectric or a semiconductor) has a thickness, tᵢₙₜ, no more than 100 nm. Preferably, the interfacial layer 22 has a thickness of about 50 nm.

### Third Power Semiconductor Device

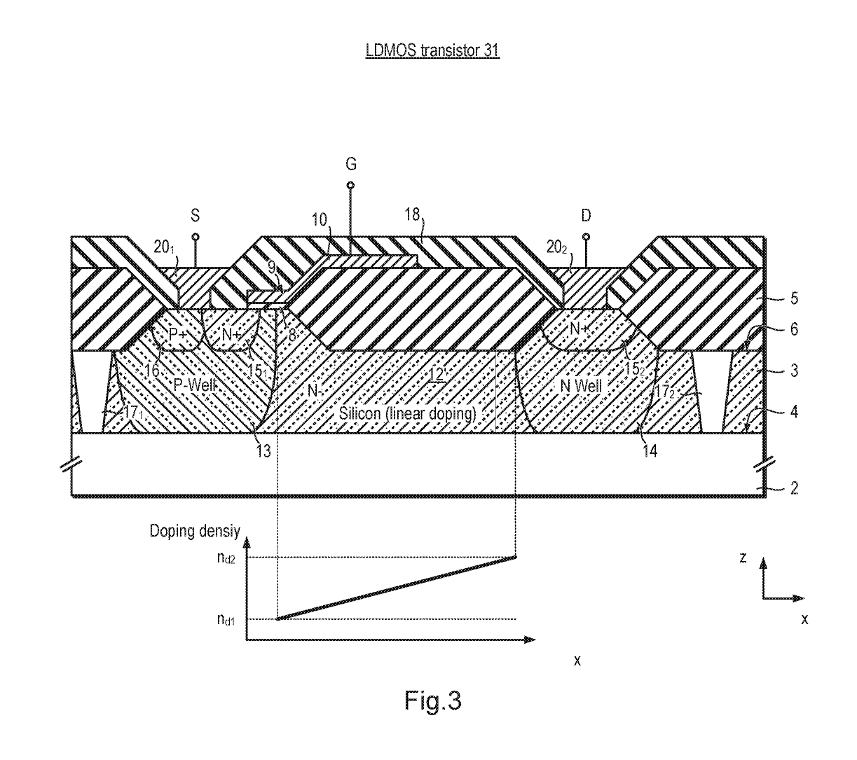

Referring to FIG. 3, a third power semiconductor device comprising a third LDMOS transistor 31 is shown.

The third power semiconductor device is substantially the same as the first power semiconductor device except that it employs so called “linear doping” along the length of the drift region 12′ which can help to improve blocking voltage. In particular, dopant concentration in the silicon layer 3 increases from the source to the drain. The doping concentration increases by an order of magnitude, i.e. n_{d2}=10·n_{d1}, where n is the doping concentration (in this case, of donors) under the drain and n_{d1} is the doping concentration under the source.

### Fourth Power Semiconductor Device

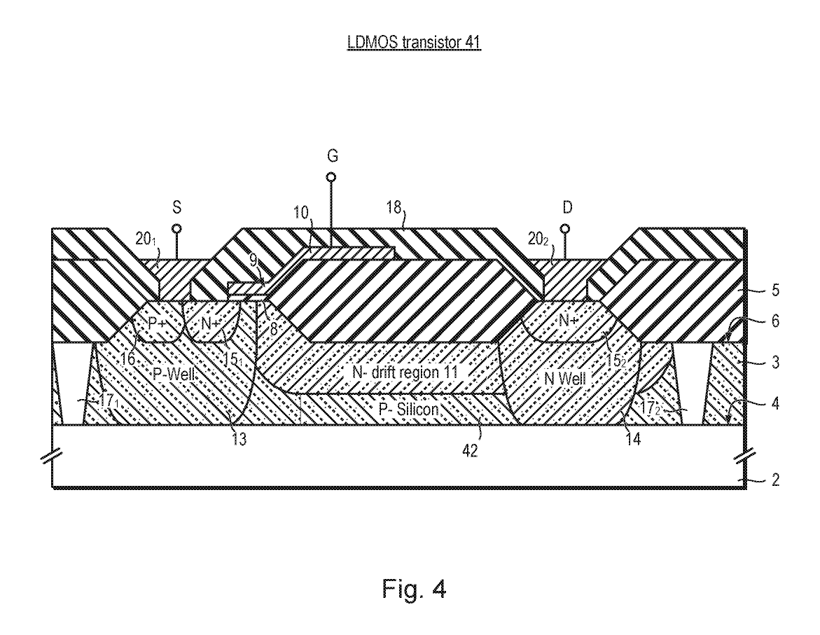

Referring to FIG. 4, a fourth power semiconductor device comprising a fourth LDMOS transistor 41 is shown.

The fourth power semiconductor device is substantially the same as the first power semiconductor device except that it employs a reduced surface field (RESURF) doping profile which can help to improve breakdown voltage and minimise on-resistance. In particular, a p-type region 42 is provided between the n-type drift region 12 and the substrate 2.

### Fifth Power Semiconductor Device

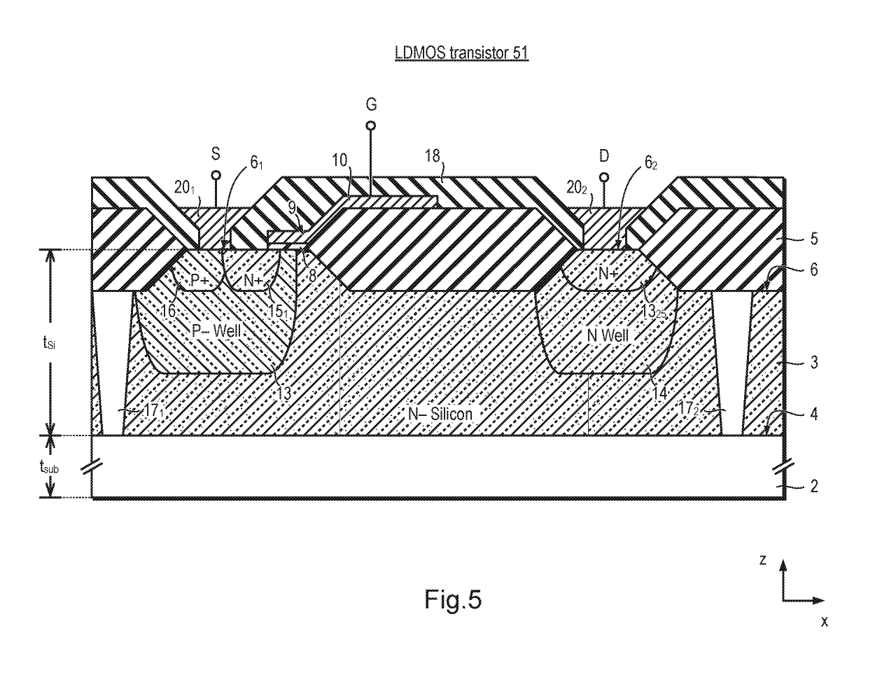

Referring to FIG. 5, a fifth power semiconductor device comprising a fifth LDMOS transistor 51 is shown.

The fifth power semiconductor device is substantially the same as the first power semiconductor device except that a thicker silicon layer 3 is used. This can shift the current rating versus breakdown voltage trade-off back toward the current throughput. In particular, the silicon layer 3 can have a thickness, t_{Si}, greater than 2 μm, up to 5 μm.

### Sixth Power Semiconductor Device

In the embodiments hereinbefore described, the lateral transistors take the form of field-effect transistors. However, the transistor can take other forms.

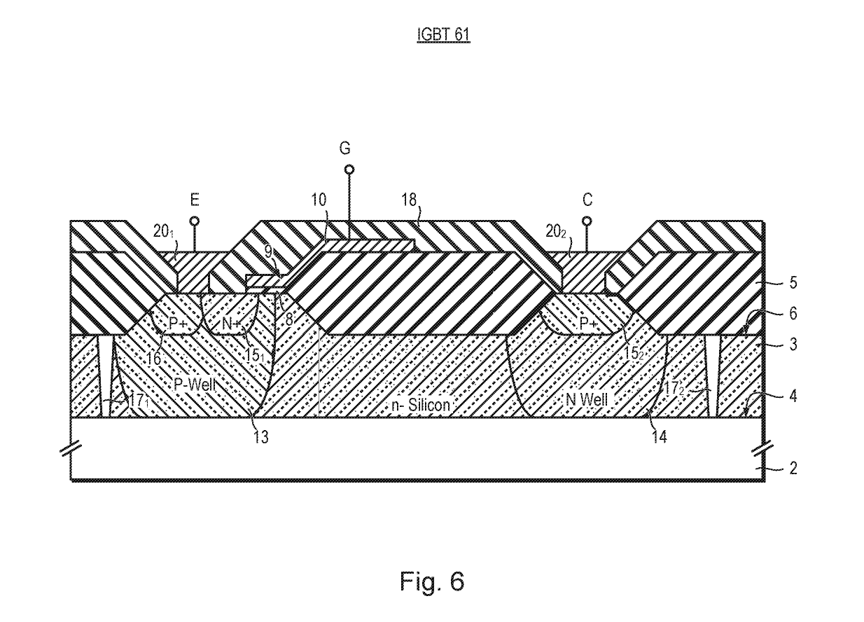

Referring to FIG. 6, a sixth power semiconductor device comprising an insulated gate bipolar transistor (IGBT) 61 is shown.

The sixth power semiconductor device is substantially the same as the first power semiconductor device except that the second contact region 15₂ is of opposite polarity type, i.e. a heavily-doped p-type shallow well which sits in the n-type body region 14. The first and second contact regions 15₁, 15₂ in this type of device are referred to as emitter and collector regions respectively.

### Fabrication

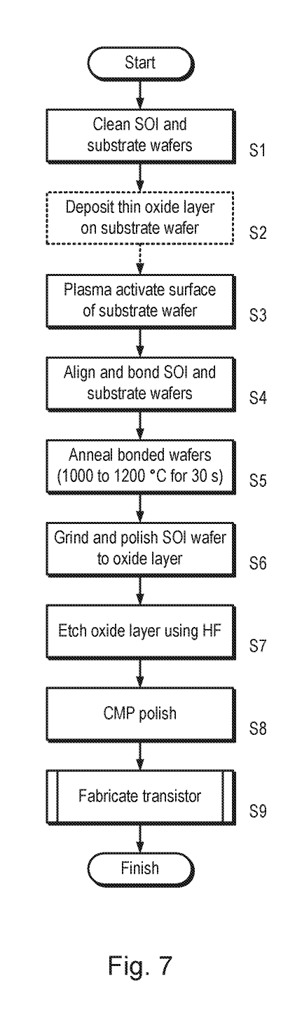

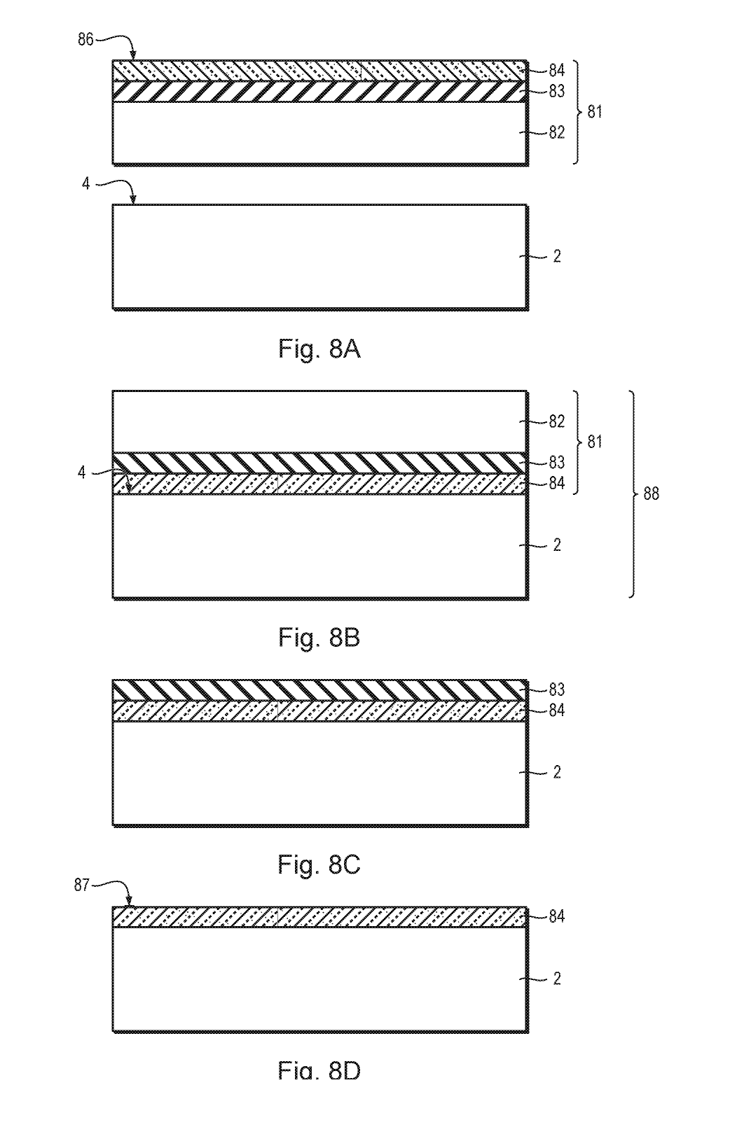

Referring to FIG. 7 and to FIGS. 8A to 8D, a method of fabricating a power semiconductor device will now be described.

An SOI wafer 81, which comprises a silicon substrate 82 (or “handle”), a buried silicon oxide layer 83 and surface oxide layer 84, and substrate wafer 2, such as a 6H-SiC wafer, are cleaned using solvent and acid dips (not shown) and a megasonic rinse (not shown) (step S1). Optionally, a thin layer of silicon dioxide (not shown) may be deposited on the surface 86 of SOI wafer 81 to render the surface hydrophilic (step S2).

The surface 86 is then plasma activated, for example, using an EVG® LT 810 Series Plasma Activation System (step S3).

The surfaces 86, 4 of the SOI wafer 81 and the substrate wafer 2 are aligned and brought together to form a composite wafer 88 (step S4). The composite wafer 88 is annealed at 1,000-1,200° C. for 30 seconds to strength interfacial bond (step S5).

The SOI wafer 81 is then ground and polished to remove the handle 82 (step S6). The oxide layer 83 is then removed using hydrofluoric acid (not shown) (step S7) and the resulting surface 87 is chemically-mechanically polished (step S8) to thin the silicon layer 84 to produce the silicon layer 3 (FIG. 1) of the desired thickness.

The transistor is then fabricated (step S9). This may start with forming the field oxide 5 (FIG. 1) at the surface of the silicon layer 3 by thermal oxidation using a LOCOS process. The transistors can be fabricated in a manner well known per se.

### Simulated Device Characteristics

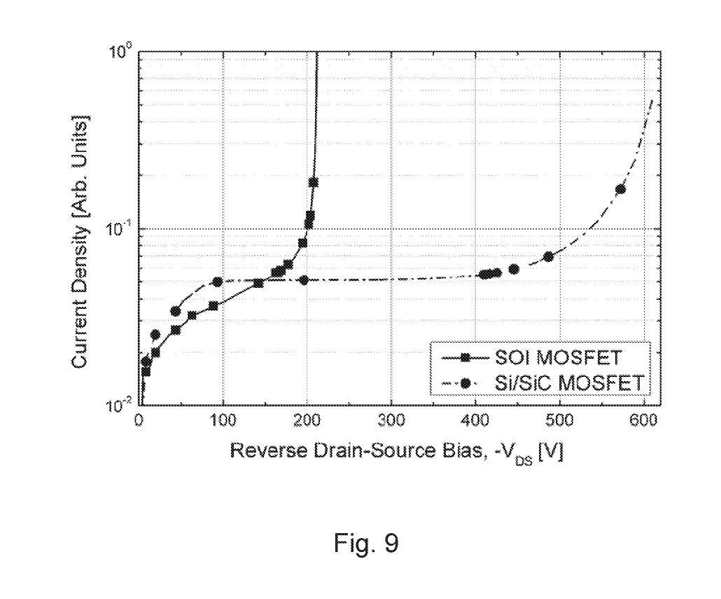

Referring to FIGS. 9, 10 and 11, simulated characteristics, carried out using SILVACO® Atlas software, of a LDMOS transistor (“Si/SiC MOSFET”) having a layer of silicon disposed directly on an semi-insulating 6H-SiC substrate and a comparative example in the form of an LDMOS transistor (“SOI MOSFET”) disposed on a silicon-on-insulator (SOI) substrate comprising of type a p-doped handle wafer (N_{A}=1×10¹⁷ cm⁻³) and 1 μm of buried oxide are shown.

Both transistors have the same structure and dimensions. The transistors have a layer of silicon having a thickness of 2 μm. The drift region is 45 μm long between source and drain regions and narrows to 1 μm beneath the field oxide.

For the Si/SiC MOSFET, the drift region is lightly n-doped Si (N_{D}=1×10¹⁵ cm⁻³). For the SOI MOSFET, however, linear doping is used so increasing the doping in the drift region from N_{D}=1×10¹⁵ cm⁻³ at the source to N_{D}=1×10¹⁶ cm⁻³ at the drain so as to maximise the breakdown voltage of the transistor.

FIG. 9 shows simulated breakdown voltages in which source-to-drain voltage is increased until leakage current begins to rise exponentially. As seen in FIG. 1, despite having similar structures, the Si/SiC MOSFET reaches 600 V, compared to 210 V for the linearly doped SOI MOSFET (without the linear doping, the breakdown voltage is just 110 V).

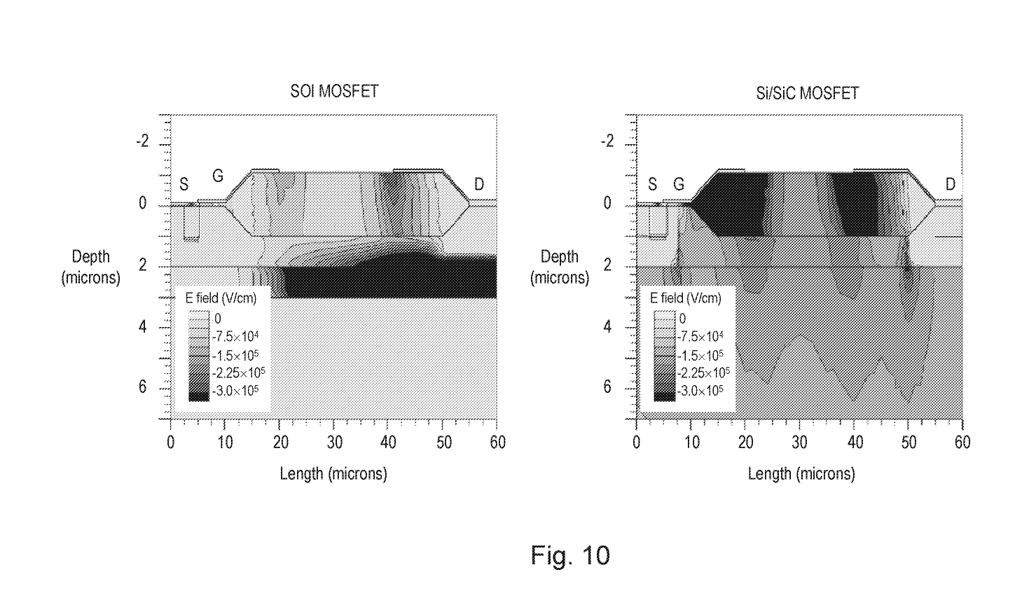

FIG. 10 shows electric field distribution in the Si/SiC and SOI MOSFETs at the point of avalanche breakdown. The contours (which are black when they exceed the critical electric field of Si) are shown to have very different distributions in each of the device structures.

In the SOI MOSFET, the electric field is highly concentrated towards the drain end of the drift region, with the insulating buried oxide not allowing any significant vertical spreading of the electric field.

In the Si/SiC MOSFET, however, there is significant vertical spreading of the electric field into the substrate. This results in a more even spread of the electric field laterally along the drift region from source to drain.

Self-heating characteristics of the Si/SiC and SOI MOSFETs are tested by looking at the forward bias characteristics.

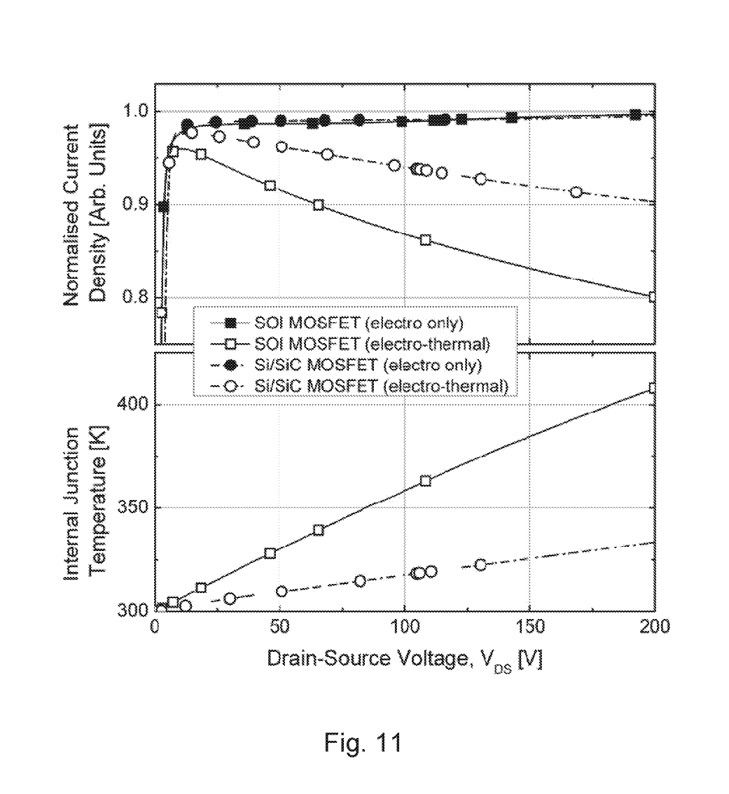

Referring to FIG. 11, the solid shapes represent the output J_{DS}-V_{DS} characteristics of each device, without considering the effects of temperature. A gate bias of 7V is applied to each device and is driven well into the saturation region as V_{DS} is ramped up thereby increasing the power dissipated in the device. The hollow shapes represent results using electro-thermal simulations. The bottom graph shows the localised temperature of the devices as V_{DS} is ramped up. The decreasing current is an effect known as negative resistance, where the rise in temperature causes the internal resistance of the drift region to rise, reducing the total current throughput. At V_{DS}=200 V, self-heating is responsible for a 10% reduction in current throughput in the Si/SiC MOSFET compared to a 20% reduction in the SOI MOSFET. Furthermore, the internal junction temperature of the SOI MOSFET at this point has risen by 108° C., a temperature rise over three times greater than the Si/SiC MOSFET.

### Modifications

It will be appreciated that various modifications may be made to the embodiments hereinbefore described. Such modifications may involve equivalent and other features which are already known in the design, manufacture and use of power semiconductor devices and component parts thereof and which may be used instead of or in addition to features already described herein. Features of one embodiment may be replaced or supplemented by features of another embodiment. For example, the interfacial layer of the second power semiconductor device may be used in combination with the linear doping of the second power semiconductor device.

The transistors may be p-type rather than n-type. Thus, a p-type silicon layer may be used and the body regions and contact regions may be of a suitable conductivity type.

A semi-insulating 6H-SiC substrate need not be used. An n- or p-type doped 6H-SiC substrate can be used. Other polytypes of SiC, such as 4H-SiC, can be used.

Substrates other than SiC which have high thermal conductivity can be used such as, for example, diamond or aluminium nitride (AlN).

The silicon layer need not be formed by wafer bonding a silicon-on-insulator wafer onto a substrate wafer (with or without a thin dielectric layer), grinding back the handle wafer, etching (using hydrofluoric acid) the oxide and polishing the surface. The silicon layer can be formed using Smartcut®. The silicon layer can be formed by bonding a silicon wafer to a substrate wafer (with or without a thin dielectric layer), then grinding back and polishing the silicon wafer. The silicon wafer can be formed by epitaxially growing a layer of silicon on the substrate using molecular beam epitaxy (MBE) or chemical vapour deposition (CVD).

The claims are amended as follows:

1-15. (canceled)

16. A power semiconductor device comprising:
a silicon carbide substrate;
a layer of monocrystalline silicon having a thickness no more than 5 μm disposed directly on an interfacial layer having a thickness no more than 100 nm which is disposed directly on the substrate; and
a lateral power transistor which is a laterally-diffused metal oxide semiconductor transistor or insulated gate bipolar transistor, the transistor comprising:
first and second contact laterally-spaced contact regions disposed in the monocrystalline silicon layer, and
a drift region disposed in the monocrystalline silicon layer.

17. A device according to claim 16, wherein the substrate comprises a 4H-SiC substrate.

18. A device according to claim 16 or 17, wherein the substrate is semi-insulating.

19. A device according to claim 16, wherein the substrate has a thickness no more than 300 μm.

20. A device according to claim 16, wherein the substrate has a thickness no more than 50 μm.

21. A device according to claim 16, wherein the monocrystalline silicon layer has a thickness no more than 2 μm.

22. A device according to claim 16, wherein the monocrystalline silicon layer has a thickness no more than 1 μm.

23. A device according to claim 16, wherein the monocrystalline silicon layer has a thickness no more than 300 nm.

24. A device according to claim 16, wherein the monocrystalline silicon layer comprises an n-type region or p-type region.

25. A device according to claim 16, wherein the interfacial layer comprises a dielectric material.

26. A device according to claim 16, wherein the interfacial layer comprises a semiconductor material.

27. A method of operating a device according to claim 16 at a temperature of at least 200° C., the method comprising:
applying a drain-source voltage of at least 100 V.

28. A method according to claim 27, comprising:
applying a drain-source voltage up to 600 V.

29. A device according to claim 16, wherein the lateral device is operable at a temperature of at least 200° C. and a drain-source voltage of at least 100 V.

30. A device according to claim 16, wherein the interfacial layer has a thickness no more than 50 nm.

31. A device according to claim 16, wherein the interfacial layer has a thickness of up to 5 nm.
